(19) United States
(12) Patent Application Publication
(10) Pub. No.: US 2024/0407163 A1
(43) Pub. Date: Dec. 5, 2024

(54) NOR-TYPE MEMORY DEVICE, METHOD OF MANUFACTURING NOR-TYPE MEMORY DEVICE, AND ELECTRONIC DEVICE INCLUDING MEMORY DEVICE

(71) Applicant: INSTITUTE OF MICROELECTRONICS, CHINESE ACADEMY OF SCIENCES, Beijing (CN)

(72) Inventors: Zijin YAN, Beijing (CN); Huilong ZHU, Poughkeepsie, NY (US)

(73) Assignee: INSTITUTE OF MICROELECTRONICS, CHINESE ACADEMY OF SCIENCES, Beijing (CN)

(21) Appl. No.: 18/388,233

(22) Filed: Nov. 9, 2023

(30) Foreign Application Priority Data
May 31, 2023 (CN) 202310635657.4

(51) Int. Cl. H10B 43/27; H10B 43/10

(52) U.S. Cl. CPC H10B 43/27; H10B 43/10

(57) ABSTRACT

Provided are a NOR-type memory device, a manufacturing method, and an electronic device. The device includes: a plurality of gate stacks extending vertically on a substrate, wherein the gate stack includes a first gate conductor layer and a first filling layer; at least one device layer surrounding a periphery of the gate stack and extending along a sidewall of the gate stack; and a single-crystal vertical channel on a side of the device layer close to the gate stack and in contact with the first filling layer. At least one side surface of the gate stack in the vertical direction is a (100) or (110) crystal plane; and/or the body region includes a second filling layer or the body region includes a second gate conductor layer and a third filling layer, wherein at least one of first and third filling layers is a storage functional layer.

### CROSS REFERENCE TO RELATED APPLICATION

This application claims priority to Chinese Patent Application No. 202310635657.4, filed on May 31, 2023, the entire content of which is incorporated herein in its entirety by reference.

### TECHNICAL FIELD

The present disclosure relates to a technical field of semiconductors, and in particular to a NOR-type memory device, a method of manufacturing the NOR-type memory device, and an electronic device including the memory device.

### BACKGROUND

NOR Flash is a nonvolatile flash memory technology, which is widely used in daily life, such as a USB disk, a SSD hard disk, and the like. A NOR-type memory device may be read and written in bytes, and have advantages such as a high reading speed, a direct reading and writing of programs, and the like. However, a low integration level of the NOR-type memory device limits its application scenarios.

The related art increases an integration density by vertically stacking devices. For example, polycrystalline silicon is commonly used as a channel material, but a resistance of the polycrystalline silicon material is large, which leads to a poor overall performance of the device.

### SUMMARY

### (I) Technical Problems to be Solved

In response to the existing technical problems, the present disclosure provides a NOR-type memory device, a method of manufacturing the NOR-type memory device, and an electronic device including the memory device, for at least partially solving the above-mentioned technical problems.

### (II) Technical Solutions

The present disclosure provides a NOR-type memory device, including: a plurality of gate stacks extending vertically on a substrate, wherein the gate stack includes a first gate conductor layer and a first filling layer; at least one device layer surrounding a periphery of the gate stack and extending along a sidewall of the gate stack, wherein the device layer includes at least two source/drain regions and at least one body region provided in a vertical direction, the source/drain regions and the body region are provided alternatively, and a memory cell is defined at an intersection of the gate stack and the body region; and a vertical channel provided on a side of the device layer close to the gate stack, wherein the vertical channel is a single crystal channel and in contact with the first filling layer; wherein at least one side surface of the gate stack in the vertical direction is a (100) crystal plane or a (110) crystal plane; and/or the body region adopts any one of following two structures: the body region includes a second filling layer, wherein the second filling layer is a first insulation layer or a stress layer, and the stress layer is used to apply a stress to the vertical channel, or the body region includes a second gate conductor layer and a third filling layer, wherein the third filling layer is used to isolate the second gate conductor layer from the source/drain region, and at least one of the first filling layer and the third filling layer is a storage functional layer.

Optionally, a material of the first insulation layer includes silicon oxide, aluminum oxide, hafnium oxide, zirconia, and silicon oxynitride, and a material of the stress layer includes silicon carbide, silicon germanium, and silicon nitride.

Optionally, the storage functional layer includes a tunneling layer, a charge capture layer, and a barrier layer stacked sequentially, wherein the barrier layer is provided on a side close to the first gate conductor layer and/or the second gate conductor layer, and a material of the barrier layer includes at least one of aluminum oxide and silicon oxide, a material of the charge capture layer includes hafnium oxide, zirconia, and silicon nitride, and a material of the tunneling layer includes aluminum oxide, silicon oxide, and silicon oxynitride.

Optionally, the NOR-type memory device further includes: a first leading electrode and a second leading electrode, wherein the first leading electrode is electrically connected to the source/drain region, and the second leading electrode is electrically connected to the second gate conductor layer.

Optionally, the NOR-type memory device further includes: a plurality of surface electrodes; wherein the plurality of surface electrodes are electrically connected to the first leading electrode and the second leading electrode, respectively.

Optionally, a material of the vertical channel includes monocrystalline silicon, silicon carbide, a III-V group compound, and graphene, and the material of the vertical channel is an in-situ doped material; wherein, when the vertical channel is a P-type metal oxide semiconductor, a doping element includes sulfur and arsenic, and when the vertical channel is an N-type metal oxide semiconductor, a doping element includes boron.

Optionally, a thickness of the vertical channel is between 1 nm and 100 nm.

Optionally, the NOR-type memory device includes: at least two device layers, wherein a second insulation layer is provided between respective device layers of the at least two device layers.

Optionally, the NOR-type memory device further includes: a plurality of support columns and a plurality of hollowing-out columns, wherein the support column and the hollowing-out column penetrate through the device layer in the vertical direction, the support column is used to support the source/drain region, and the hollowing-out column is used to assist in hollowing out the body region.

Optionally, projections of the support columns, the hollowing-out columns, and the gate stacks on the substrate are arranged in a first direction, wherein any one or more of the support columns, the hollowing-out columns, and the gate stacks have a plurality of rows of projections on the substrate, and each of the plurality of rows of projections is arranged in a cross manner or arranged in parallel in a second direction.

Another aspect of the present disclosure provides a method of manufacturing a NOR-type memory device, including: epitaxially growing at least one device layer on a substrate, wherein the device layer includes at least two source/drain regions and at least one intra-group sacrificial layer provided in a vertical direction, and the source/drain regions and the intra-group sacrificial layer are provided alternatively; forming a plurality of support columns, a plurality of hollowing-out holes, and a plurality of gate holes, which extend vertically relative to the substrate to pass through the device layer; epitaxially growing, through the gate hole, a vertical channel on a sidewall of the device layer; forming a gate stack in the gate hole, wherein at least one side surface of the gate hole in the vertical direction is a (100) crystal plane or a (110) crystal plane, and the gate stack includes a first gate conductor layer and a first filling layer provided between the first gate conductor layer and the vertical channel; and etching the intra-group sacrificial layer through the hollowing-out hole, so as to obtain a body region, wherein a memory cell is defined at an intersection of the gate stack and the body region.

Optionally, after obtaining the body region, the method further includes: growing, through the hollowing-out hole, a second filling layer in the body region, wherein the second filling layer is a first insulation layer or a stress layer.

Optionally, after obtaining the body region, the method further includes: growing, through the hollowing-out hole, a third filling layer in the body region and on the source/drain region and the vertical channel; and growing a second gate conductor layer on the third filling layer until the body region is fully filled, wherein at least one of the first filling layer and the third filling layer is a storage functional layer.

Optionally, the method further includes: forming a first leading electrode hole which extends vertically relative to the substrate to the source/drain region; forming a second leading electrode hole which extends vertically relative to the substrate to the second gate conductor layer; growing a third insulation layer on side walls of the first and second leading electrode holes; and growing a leading electrode on the third insulation layer in the first leading electrode hole and on the source/drain region, so as to obtain a first leading electrode; and growing a leading electrode on the third insulation layer in the second leading electrode hole and on the second gate conductor layer, so as to obtain a second leading electrode.

Optionally, at least two device layers are epitaxially grown on the substrate, wherein an inter-group sacrificial layer is grown between respective device layers of the at least two device layers, and a thickness of the inter-group sacrificial layer is greater than a thickness of the intra-group sacrificial layer; after forming the support column, the hollowing-out hole, and the gate hole, the method further includes: etching, through the hollowing-out hole, a portion of the intra-group sacrificial layer and a portion of the inter-group sacrificial layer, so as to obtain an intra-group trench and an inter-group trench; synchronously growing a filling medium in the intra-group trench and the inter-group trench until the intra-group trench is fully filled; selectively etching the filling medium in the inter-group trench and the inter-group sacrificial layer, so as to obtain an inter-group cavity; and filling the inter-group cavity with an insulating medium to obtain a second insulation layer.

Optionally, etching the intra-group sacrificial layer through the hollowing-out hole to obtain the body region includes: selectively etching, through the hollowing-out hole, the filling medium in the intra-group trench and the intra-group sacrificial layer, so as to obtain the body region.

Optionally, epitaxially growing the vertical channel on the sidewall of the device layer through the gate hole includes: epitaxially growing the vertical channel on the sidewall of the device layer by using a reduced pressure chemical vapor deposition method.

Optionally, forming a gate stack in the gate hole includes: growing the first filling layer on a side surface and a bottom surface of the gate hole; and growing the first gate conductor layer on the first filling layer until the gate hole is fully filled, so as to obtain the gate stack.

A third aspect of the present disclosure provides an electronic device, including a NOR-type memory device according to any embodiment of the present disclosure.

Optionally, the electronic device includes: a smart phone, a personal computer, a tablet computer, an artificial intelligence device, a wearable device, and a mobile power supply.

### (III) Beneficial Effects

Compared with the prior art, the NOR-type memory device, the method of manufacturing the NOR-type memory device, and the electronic device including the memory device provided in the present disclosure have at least following beneficial effects:
(1) The NOR-type memory device of the present disclosure greatly improves a mobility of a channel by providing a vertical single crystal channel between the device layer and the gate stack, in combination with providing a side surface of the channel as a (100) crystal plane or a (110) crystal plane, thereby improving a read and write performance of the NOR-type memory device.
(2) The NOR-type memory device of the present disclosure may optimize a structural stability of the NOR-type memory device and an insulation performance between the source/drain regions of the device by providing an insulation layer in the body region. Alternatively, a stress layer is provided in the body region to apply a stress to the vertical channel, which may further improve the mobility of the channel.
(3) The NOR-type memory device of the present disclosure may greatly increase the number of memory cells of the NOR-type memory device by providing a lateral gate conductor layer and a third filling layer in the body region, which improves a storage capacity of the NOR-type memory device.
(4) The method of manufacturing a NOR-type memory device in the present disclosure simplifies, by providing support columns, hollowing-out columns, and gate holes respectively, a manufacturing process of the body region in the device layer and simplifies a manufacturing process of the isolation layer between respective device layers in the multi-layer device layer, achieving multi-layer three-dimensional stacking of the NOR-type memory device.

### BRIEF DESCRIPTION OF THE DRAWINGS

The above and other objectives, features and advantages of the present disclosure will be more apparent through the following description of embodiments of the present disclosure with reference to the accompanying drawings.

FIG. 1A schematically shows a cross-sectional view of a structure of a NOR-type memory device according to an embodiment of the present disclosure.

FIG. 1B schematically shows a top view of a structure of a NOR-type memory device according to an embodiment of the present disclosure.

FIG. 1C schematically shows a top view of a structure of a NOR-type memory device according to another embodiment of the present disclosure.

FIG. 2A schematically shows a cross-sectional view of a structure of a NOR-type memory device according to another embodiment of the present disclosure.

FIG. 2B schematically shows a top view of a structure of a NOR-type memory device according to yet another embodiment of the present disclosure.

FIG. 3 schematically shows a cross-sectional view of a structure of a NOR-type memory device according to yet another embodiment of the present disclosure.

FIG. 4 schematically shows a cross-sectional view of a structure of a NOR-type memory device according to yet another embodiment of the present disclosure.

FIG. 5 schematically shows a method diagram of manufacturing a NOR-type memory device according to an embodiment of the present disclosure.

FIG. 6A schematically shows a cross-sectional view of a structure of a stack during a manufacturing process of a NOR-type memory device according to an embodiment of the present disclosure.

FIG. 6B schematically shows a cross-sectional view of a structure of a hole during a manufacturing process of a NOR-type memory device according to an embodiment of the present disclosure.

FIG. 6C schematically shows a cross-sectional view of a structure of a vertical channel during a manufacturing process of a NOR-type memory device according to an embodiment of the present disclosure.

FIG. 6D schematically shows a cross-sectional view of a structure of a gate stack during a manufacturing process of a NOR-type memory device according to an embodiment of the present disclosure.

FIG. 6E schematically shows a cross-sectional view of a structure of a body region during a manufacturing process of a NOR-type memory device according to an embodiment of the present disclosure.

FIG. 6F schematically shows a cross-sectional view of a structure of a body region during a manufacturing process of a NOR-type memory device according to another embodiment of the present disclosure.

FIG. 6G schematically shows a cross-sectional view of a structure of a body region during a manufacturing process of a NOR-type memory device according to yet another embodiment of the present disclosure.

FIG. 6H schematically shows a cross-sectional view of a structure of a leading electrode during a manufacturing process of a NOR-type memory device according to an embodiment of the present disclosure.

FIG. 7A schematically shows a cross-sectional view of a structure of a stack during a manufacturing process of a NOR-type memory device according to another embodiment of the present disclosure.

FIG. 7B schematically shows a cross-sectional view of a structure of a trench obtained by etching a portion of a sacrificial layer during a manufacturing process of a NOR-type memory device according to an embodiment of the present disclosure.

FIG. 7C schematically shows a cross-sectional view of a structure of a protection plug obtained by filling a trench with a medium during a manufacturing process of a NOR-type memory device according to an embodiment of the present disclosure.

FIG. 7D schematically shows a cross-sectional view of a structure of an inter-group cavity obtained by etching a filling medium and an inter-group sacrificial layer during a manufacturing process of a NOR-type memory device according to an embodiment of the present disclosure.

FIG. 7E schematically shows a cross-sectional view of a structure of a body region during a manufacturing process of a NOR-type memory device according to another embodiment of the present disclosure.

### DESCRIPTION OF REFERENCE SIGNS

1—Substrate; 2—Gate stack; 20—Gate hole; 201—Gate column; 21—First gate conductor layer; 22—First filling layer; 3—Device layer; 30—Intra-group sacrificial layer; 301—Intra-group trench; 302—Protection plug; 31—Source/drain region; 32—Body region; 321—Second filling layer; 322—Second gate conductor layer; 323—Third filling layer; 4—Vertical channel; 5—Second insulation layer; 50—Inter-group sacrificial layer; 501—Inter-group trench; 502—Gap; 503—Inter-group cavity; 6—First leading electrode; 7—Second leading electrode; 8—Surface electrode; 9—Support column; 10—Hollowing-out column; 11—Hollowing-out hole.

### DETAILED DESCRIPTION OF EMBODIMENTS

In order to make objectives, technical solutions and advantages of the present disclosure more apparent and understandable, the present disclosure is further described in detail below in combination with specific embodiments and with reference to the accompanying drawings.

It should be noted that in the accompanying drawings or the description of the specification, the same reference signs are used for similar or identical parts. The technical features of the various embodiments illustrated in the specification may be freely combined to form a new solution without conflict. In addition, each claim may be used as a separate embodiment or the technical features of the claims may be combined as a new embodiment. In the accompanying drawings, the shape or thickness of the embodiments may be enlarged, and indicated with simplicity or convenience. Furthermore, the elements or implementations not shown or described in the accompanying drawings are in a form known to those of ordinary skill in the art. Additionally, although examples of parameters including particular values may be provided herein, it should be appreciated that the parameters need not be exactly equal to the respective values, but may approximate the respective values within acceptable error margins or design constraints.

Unless there are technical obstacles or contradictions, the various embodiments described above in the present disclosure may be freely combined to form additional embodiments, which all fall in the scope of protection of the present disclosure.

Although the present disclosure has been described in combination with the accompanying drawings, the embodiments disclosed in the accompanying drawings are intended to illustrate the preferred embodiments of the present disclosure, and are not to be understood as limiting the present disclosure. The dimensional proportions in the accompanying drawings are only schematic and are not to be understood as limiting the present disclosure.

Although some embodiments of the overall concept of the present disclosure have been shown and explained, those of ordinary skill in the art will understand that changes may be made to these embodiments without departing from the principle and spirit of the overall concept of the present disclosure. The scope of the present disclosure is defined by the claims and their equivalents.

According to embodiments of the present disclosure, the NOR-type memory device includes, for example, a plurality of gate stacks 2 extending vertically on a substrate 1, wherein the gate stack 2 includes a first gate conductor layer 21 and a first filling layer 22; at least one device layer 3 surrounding a periphery of the gate stack 2 and extending along a sidewall of the gate stack 2, wherein the device layer 3 includes at least two source/drain regions 31 and at least one body region 32 provided in a vertical direction, the source/drain regions 31 and the body region 32 are provided alternatively, and a memory cell is defined at an intersection of the gate stack 2 and the body region 32; and a vertical channel 4 provided on a side of the device layer 3 close to the gate stack 2, wherein the vertical channel 4 is a single crystal channel and in contact with the first filling layer 22. At least one side surface of the gate stack 2 in the vertical direction is a (100) crystal plane or a (110) crystal plane; and/or the body region 32 adopts any one of following two structures: the body region 32 includes a second filling layer 321, wherein the second filling layer 321 is a first insulation layer or a stress layer, and the stress layer is used to apply a stress to the vertical channel 4; or the body region 32 includes a second gate conductor layer 322 and a third filling layer 323, wherein the third filling layer 323 is used to isolate the second gate conductor layer 322 from the source/drain region 31, and at least one of the first filling layer 22 and the third filling layer 323 is a storage functional layer.

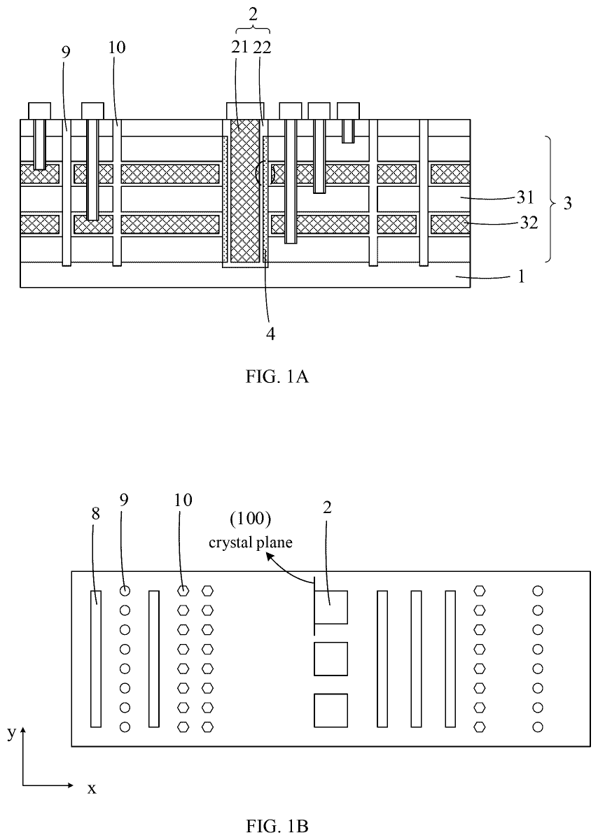

FIG. 1A schematically shows a cross-sectional view of a structure of a NOR-type memory device according to an embodiment of the present disclosure. FIG. 1B schematically shows a top view of a structure of a NOR-type memory device according to an embodiment of the present disclosure. FIG. 1C schematically shows a top view of a structure of a NOR-type memory device according to another embodiment of the present disclosure.

For example, as shown in FIG. 1A, the NOR-type memory device may be provided with a device layer 3 on the substrate 1, and the device layer 3 includes three layers of source/drain regions 31 and two layers of body regions 32 provided alternatively. The body region 32 is a space-based region definition regardless of a fill state of the region and what material is filled. For example, the first filling layer 22 covers the vertical channel 4, so as to form a memory cell at the dashed circle in FIG. 1A.

It may be understood that the dashed circle in FIG. 1A only schematically shows an intersection of one body region and the gate stack. As shown in FIG. 1B, memory cells are formed at the intersections of each layer of the body regions with the gate stack along the periphery of the gate stack.

For example, as shown in FIG. 1B, the NOR-type memory device may be provided with three gate stacks 2 on the substrate 1. The substrate 1 may be a P-type substrate, and the corresponding source/drain region 31 may be N-type silicon. For this NMOS (Negative channel-Metal-Oxide-Semiconductor) device, at least one side surface of the gate stack 2 in the vertical direction is a (100) crystal plane.

For example, as shown in FIG. 1C, the substrate 1 may also be an N-type substrate, and the corresponding source/drain region 31 may be P-type silicon. For this PMOS (Positive channel-Metal-Oxide-Semiconductor) device, at least one side surface of the gate stack 2 in the vertical direction is a (110) crystal plane.

It may be understood that a shape of a projection of the gate stack 2 on the substrate may be a rectangle (including a square), for example, four sides of the gate stack 2 in FIG. 1B correspond to the (100) crystal plane, or may be other shapes such as a triangle, a diamond, etc., as long as there is at least one side of the gate stack 2 corresponds to the (100) crystal plane, so as to increase the mobility of the vertical channel 4 grown along the crystal plane. The number of the gate stacks 2 is not limited to 3, and may be more.

For example, a material of the vertical channel 4 may be any one of monocrystalline silicon, silicon carbide, III-V compound and Graphene, and the material of the vertical channel 4 is an in-situ doped material. When the material of the vertical channel 4 is monocrystalline silicon, the mobility may be improved by providing a plane where the vertical channel 4 is located as a (100) or (110) crystal plane. When the material of the vertical channel 4 is silicon, silicon carbide, III-V compound or Graphene, the mobility may be improved by providing a stress layer to apply a stress to the vertical channel 4. When the vertical channel 4 is a P-type metal oxide semiconductor, a doping element may be sulfur or arsenic. When the vertical channel 4 is an N-type metal oxide semiconductor, a doping element may be boron.

It should be noted that the material of the vertical channel 4 may be the same as or different from the material of the source/drain region 31.

For example, the thickness of the vertical channel 4 may range from 1 nm to 100 nm.

According to embodiments of the present disclosure, the NOR-type memory device includes, for example, at least two device layers 3. A second insulation layer 5 is provided between respective device layers 3 of the at least two device layers 3.

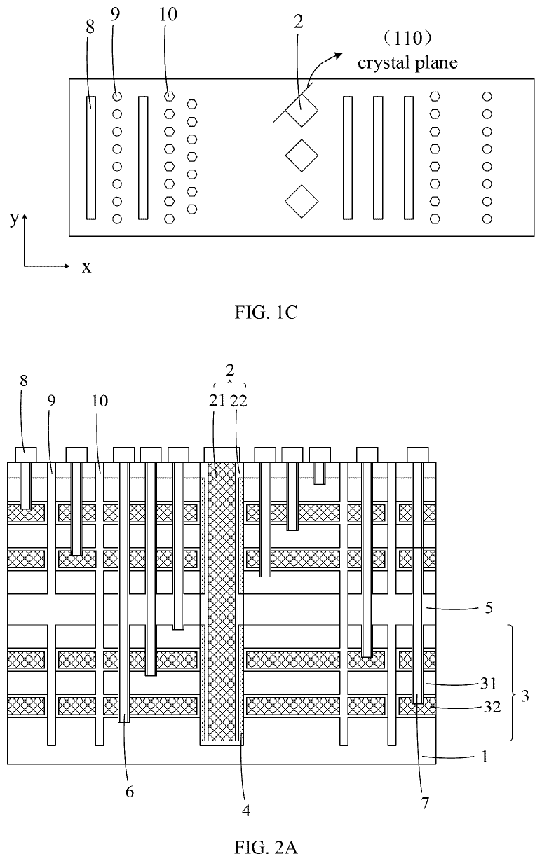

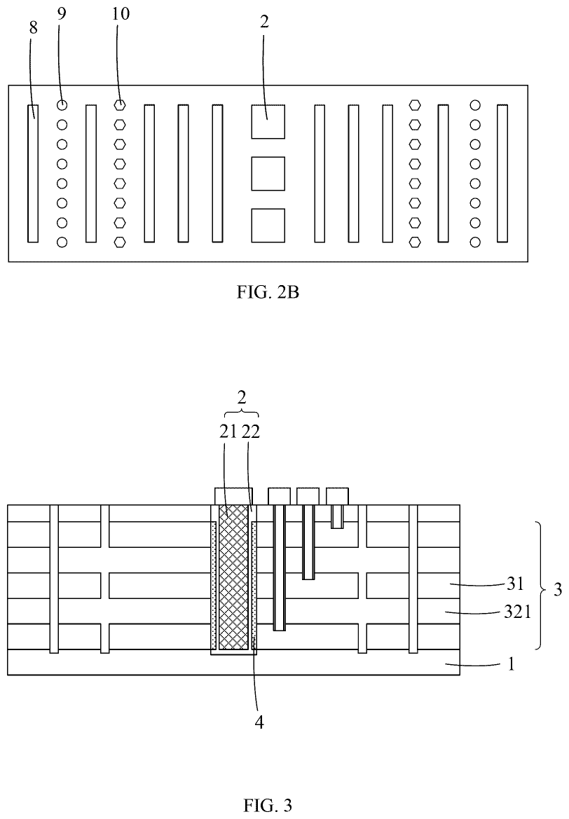

FIG. 2A schematically shows a cross-sectional view of a structure of a NOR-type memory device according to another embodiment of the present disclosure. FIG. 2B schematically shows a top view of a structure of a NOR-type memory device according to yet another embodiment of the present disclosure.

For example, as shown in FIG. 2A, the NOR-type memory device may be provided with two device layers 3 on the substrate 1, and each device layer 3 includes three layers of source/drain regions 31 and two layers of body regions 32 provided alternatively. The two device layers 3 are isolated by a second insulation layer 5. A storage capacity of the NOR-type memory device may be greatly improved by providing a plurality of device layers.

It may be understood that the NOR-type memory device disclosed in the present disclosure may be provided with three or more device layers 3 on the substrate 1. That is, in actual operation, the device layers 3 may be stacked infinitely upwards until the current process level cannot support it. Each device layer 3 may be provided with fewer or more layers of body regions 32, with source/drain regions 31 spaced therefrom being provided accordingly.

FIG. 3 schematically shows a cross-sectional view of a structure of a NOR-type memory device according to yet another embodiment of the present disclosure.

According to embodiments of the present disclosure, as shown in FIG. 3, the body region 32 includes, for example, a second filling layer 321, and the second filling layer 321 is a first insulation layer or a stress layer. A material of the first insulation layer includes, for example, silicon oxide, aluminum oxide, hafnium oxide, zirconia, and silicon oxynitride. A material of the stress layer includes, for example, silicon carbide, silicon germanium, and silicon nitride.

For example, after hollowing out the intra-group sacrificial layer through the hollowing-out column to obtain the body region 32, the source/drain regions 31 may be isolated directly by air in the body region 32. In order to improve an insulation performance and enhance a structural stability of the device, the body region 32 may be filled with a first insulation layer to form a second filling layer 321. The material of the first insulation layer may be any one of silicon oxide, aluminum oxide, hafnium oxide, zirconia, and silicon oxynitride.

For example, the body region 32 may also be filled with a stress layer to apply a tensile stress or a compressive stress to the vertical channel 4 to enhance the mobility of the vertical channel 4, thereby improving the read and write performance of the NOR-type memory device. The material of the stress layer may be any one of silicon carbide, silicon germanide, or silicon nitride. For example, a tensile stress is applied to the vertical channel 4 in the NMOS device, while a compressive stress is applied to the vertical channel 4 in the PMOS device.

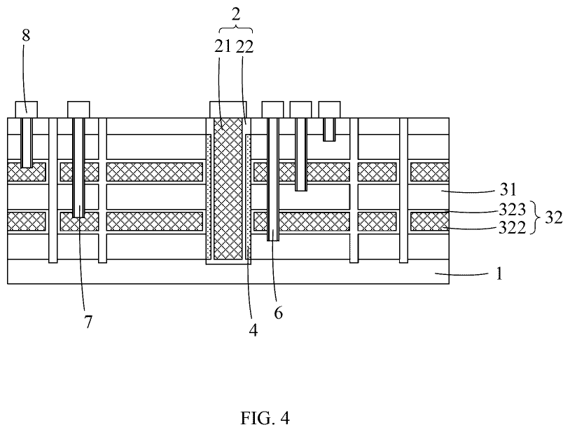

FIG. 4 schematically shows a cross-sectional view of a structure of a NOR-type memory device according to yet another embodiment of the present disclosure.

According to embodiments of the present disclosure, the body region 32 includes, for example, a second gate conductor layer 322 and a third filling layer 323. The third filling layer 323 is used to separate the second gate conductor layer 322 from the source/drain region 31. At least one of the first filling layer 22 and the third filling layer 323 is a storage functional layer.

For example, the second gate conductor layer 322 may be provided in the body region 32, that is, a back gate may be provided on a side of the vertical channel 4. When both the first filling layer 22 and the third filling layer 323 are storage functional layers, memory cells may be defined between the back gate and the vertical channel 4, as well as between the first gate conductor layer 21 and the vertical channel 4, greatly improving the storage capacity of the NOR-type memory device. Providing the second gate conductor layer 322 may also increase a current.

It may be understood that the third filling layer 323 may also be provided as the storage functional layer, while the first filling layer 22 is an insulation layer or a stress layer, which may improve an anti-crosstalk ability of the device.

It should be noted that the above-mentioned embodiments are only exemplary. The present disclosure may adopt a solution of separately providing the vertical channel 4 as a specific crystal plane, or a solution of separately providing the body region 32 as the stress layer, or a solution of separately providing the body region 32 as the second gate conductor layer 322 and the third filling layer 323, etc., or a combination of the above-mentioned solutions may be used to achieve the NOR-type memory device disclosed in the present disclosure.

For example, the storage functional layer includes a tunneling layer, a charge capture layer, and a barrier layer stacked sequentially. The barrier layer is provided on a side close to the first gate conductor layer 21 and/or the second gate conductor layer 322. A material of the barrier layer includes at least one of aluminum oxide and silicon oxide, that is, the barrier layer may be a single layer of aluminum oxide or silicon oxide, or the barrier layer may be a stack of a layer of aluminum oxide and a layer of silicon oxide. A material of the charge capture layer includes hafnium oxide, zirconia, and silicon nitride, and a material of the tunneling layer includes aluminum oxide, silicon oxide, and silicon oxynitride.

For example, the material of the storage functional layer may be silicon oxide-silicon nitride-silicon oxide, or may be a medium used for storage such as a ferroelectric material.

According to embodiments of the present disclosure, as shown in FIG. 4, the NOR-type memory device further includes, for example, a first leading electrode 6 and a second leading electrode 7. The first leading electrode 6 is electrically connected to the source/drain region 31, and the second leading electrode 7 is electrically connected to the second gate conductor layer 322.

It may be understood that the number of the first leading electrodes 6 corresponds to the number of layers of the source/drain regions 31, and the number of the second leading electrodes 7 corresponds to the number of layers of the second gate conductor layers 322.

According to embodiments of the present disclosure, as shown in FIG. 4, the NOR-type memory device further includes, for example, a plurality of surface electrodes 8. The plurality of surface electrodes 8 are electrically connected to the first leading electrode 6 and the second leading electrode 7, respectively.

For example, for single-layer device layer 3, the top view is shown in FIG. 1B, while for two-layer device layer 3, the top view is shown in FIG. 2B. A projection of the plurality of surface electrodes 8 on the substrate 1, for example, is arranged parallel in a first direction. The first direction, for example, is the x direction in FIG. 1B.

According to embodiments of the present disclosures, as shown in FIG. 1A to FIG. 1C and FIG. 2A to FIG. 2B, the NOR-type memory device further includes, for example, a plurality of support columns 9 and a plurality of hollowing-out columns 10. The support column 9 and the hollowing-out column 10 penetrate through the device layer 3 in the vertical direction, the support column 9 is used to support the source/drain region 31, and the hollowing-out column 10 is used to assist in hollowing out the body region 32.

It should be noted that a shape of a projection of the support column 9 on the substrate 1 in the top view is, for example, a circle. In order to distinguish from the circle, a shape of a projection of the hollowing-out column 10 on the substrate 1 is, for example, a regular hexagon. The shape of the projection of the support column 9 on the substrate 1 may also be a square shape or other shapes, as long as the support column 9 may be filled with a medium material to ensure that the structure does not collapse in a subsequent process. The shape of the projection of the hollowing-out column 10 on the substrate 1 may also be square shape or other shapes, as long as the subsequent hollowing-out and filling processes are satisfied.

For example, the filling material in the hollowing-out column 10 may be the same as the material in the third filling layer 323.

According to embodiments of the present disclosure, projections of the support column 9, hollowing-out column 10, and gate stack 2 on the substrate 1 are arranged in the first direction. Any one or more of the support column 9, the hollowing-out column 10, and the gate stack 2 have a plurality of rows of projections on the substrate 1 to form an array, and each of the plurality of rows of projections may be arranged in a cross manner or arranged in parallel in a second direction.

For example, the support columns 9, the hollowing-out columns 10, or the gate stacks 2 may be arranged in a single column or in an array. As shown in FIG. 1B, the projections of the support columns 9, the hollowing-out columns 10, and the gate stacks 2 on the substrate 1 are arranged in the x-direction. The hollowing-out columns 10 may be a plurality of columns arranged in parallel in the x-direction, and the hollowing-out columns 10 of adjacent two columns may be arranged in parallel in the y-direction (i.e. the second direction), or may be arranged in a cross manner, as shown in FIG. 1C.

It may be understood that FIG. 1B and FIG. 1C only show the arrangement of multiple adjacent rows of the hollowing-out columns 10, and the support columns 9 and the gate stacks 2 may also be arranged in multiple adjacent rows similar to the hollowing-out columns 10. The hollowing-out columns 10 may also be distributed on upper and lower sides of the support column 9 (from the perspective of the top view) rather than parallel to the support column 9. The number of the support columns 9, the hollowing-out columns 10, and the gate stacks 2 in the figures is only exemplary. According to actual process requirements, more support columns 9, hollowing-out columns 10, or gate stacks 2 may also be provided.

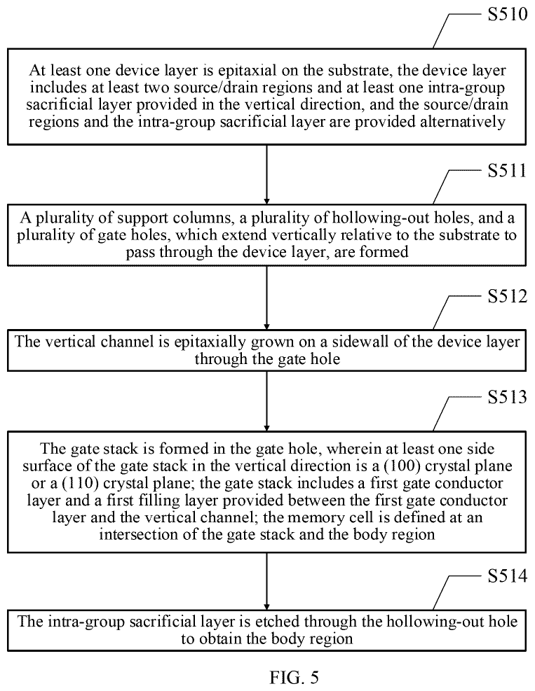

FIG. 5 schematically shows a method diagram of manufacturing a NOR-type memory device according to an embodiment of the present disclosure.

Another aspect of the present disclosure provides a method of manufacturing a NOR-type memory device, as shown in FIG. 5, and for example, the method includes the following steps S510 to S514.

In S510, at least one device layer 3 is epitaxial on the substrate 1; the device layer 3 includes at least two source/drain regions 31 and at least one intra-group sacrificial layer 30 provided in the vertical direction. The source/drain regions 31 and the intra-group sacrificial layer 30 are provided alternatively.

For example, a thickness of the epitaxial source/drain region 31 may be in a range of 10 nm to 500 nm. A thickness of the intra-group sacrificial layer 30 may be in a range of 5 nm to 500 nm.

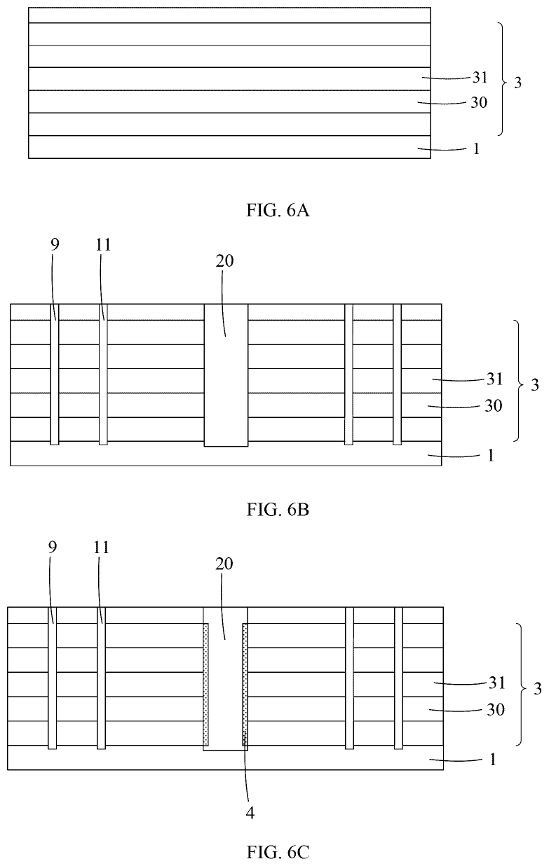

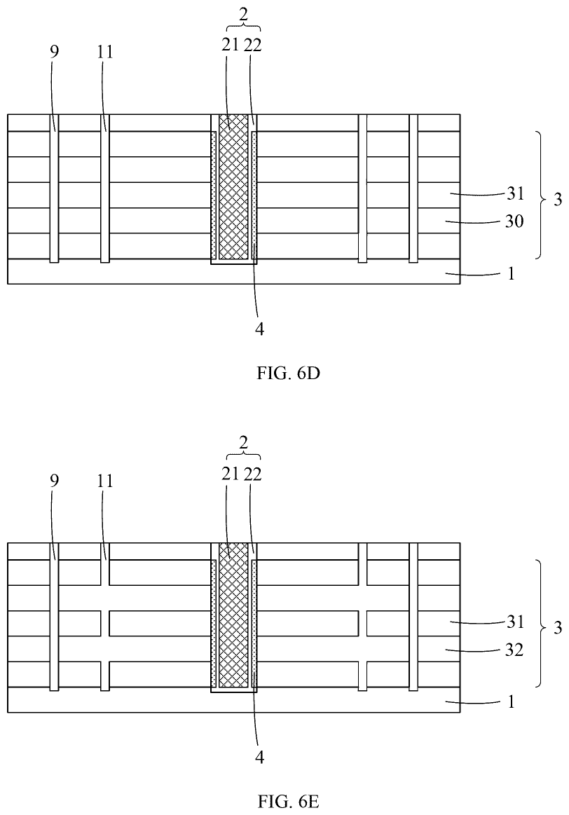

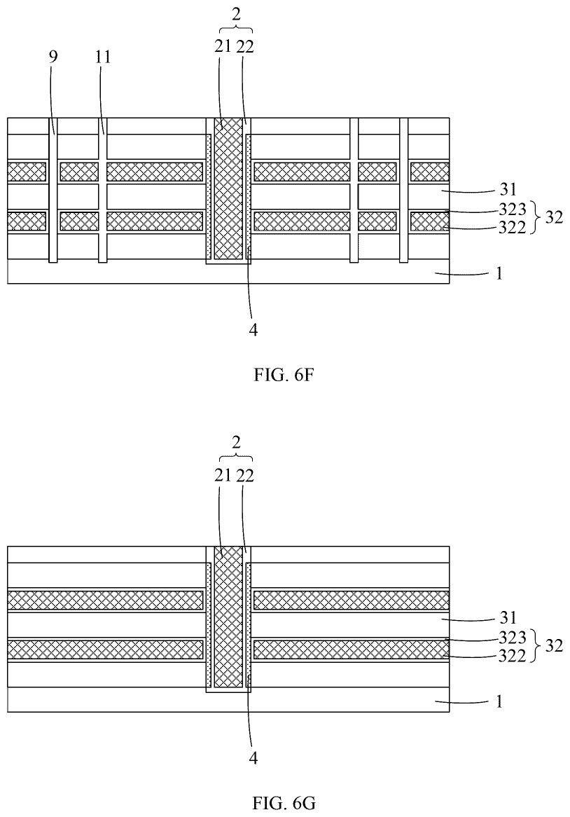

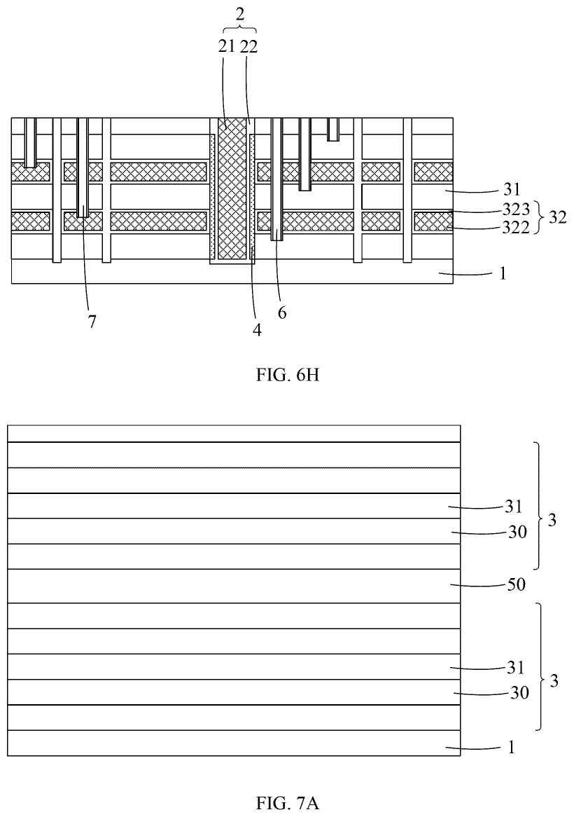

FIG. 6A schematically shows a cross-sectional view of a structure of a stack during a manufacturing process of a NOR-type memory device according to an embodiment of the present disclosure.

For example, as shown in FIG. 6A, a device layer 3 is epitaxial on the substrate 1; the device layer 3 includes three source/drain regions 31 and two intra-group sacrificial layers 30 provided alternatively. Above the device layer 3, for example, a hard mask layer is epitaxial for supporting patterning and deep silicon etching during the device preparation, and for isolating a surface electrode 8.

In S511, a plurality of support columns 9, a plurality of hollowing-out holes 11, and a plurality of gate holes 20, which extend vertically relative to the substrate 1 to pass through the device layer, are formed.

FIG. 6B schematically shows a cross-sectional view of a structure of a hole during a manufacturing process of a NOR-type memory device according to an embodiment of the present disclosure.

For example, as shown in FIG. 6B, the stack is etched by photolithography to obtain two columns of support holes, and the two columns of support holes are filled with an insulating material, such as silicon oxide, to obtain the support column 9. The stack is etched again to obtain two columns of hollowing-out holes 11 and one column of gate hole 20. The filling process includes but is not limited to, for example, ALD (Atomic layer deposition) and CVD (Chemical Vapor Deposition).

It should be noted that the support hole, the hollowing-out hole 11, and the gate hole 20 may be etched simultaneously or step by step. If etching is performed simultaneously, the support hole, the hollowing-out hole 11, and the gate hole 20 may be filled with silicon oxide simultaneously, and then the silicon oxide in the hollowing-out hole 11 and gate hole 20 is selectively etched away, and the support column 9 is reserved.

For example, the diameter of the support column 9 and the hollowing-out hole 11 may be in a range of 5 nm to 1 μm. The spacing between support columns 9 depends on the lithography and structural requirements, and is required to ensure sufficient selectivity for lateral etching to hollow out the intra-group sacrificial layer 30 and the inter-group sacrificial layer 50.

In S512, the vertical channel 4 is epitaxially grown on a sidewall of the device layer 3 through the gate hole 20.

FIG. 6C schematically shows a cross-sectional view of a structure of a vertical channel during a manufacturing process of a NOR-type memory device according to an embodiment of the present disclosure.

For example, first, the silicon oxide in the gate hole 20 is etched by photolithography, as shown in FIG. 6C, and the vertical channel 4 is formed by selective epitaxy on the sidewall of the device layer 3 in the gate hole 20. For example, reduced pressure chemical vapor deposition (RPCVD) may be used to epitaxially grow the vertical channel 4 on the sidewall of the device layer 3. The vertical channel 4 is doped by using methods such as in-situ doping and the like.

In S513, the gate stack 2 is formed in the gate hole 20, where at least one side surface of the gate hole in the vertical direction is a (100) crystal plane or a (110) crystal plane. The gate stack 2 includes a first gate conductor layer 21 and a first filling layer 22 provided between the first gate conductor layer 21 and the vertical channel 4. The memory cell is defined at an intersection of the gate stack 2 and the body region 32.

FIG. 6D schematically shows a cross-sectional view of a structure of a gate stack during a manufacturing process of a NOR-type memory device according to an embodiment of the present disclosure.

For example, a first filling layer 22 is first deposited on the sidewall and bottom surface of the gate hole 20, and the first filling layer 22 covers the hard mask, the vertical channel 4, and the substrate 1. Then, the first gate conductor layer 21 is deposited on the first filling layer 22 until the gate hole 20 is fully filled, so as to form the gate stack 2. When etching the gate hole 20, etching may be performed along the (100) crystal plane or the (110) crystal plane, so that at least one side surface of the gate stack 2 in the vertical direction is the (100) crystal plane or the (110) crystal plane. The first gate conductor layer 21 may be, for example, MG (Metal-Gate). The filling process includes but is not limited to ALD (Atomic layer deposition), CVD (Chemical Vapor Deposition), and the like. The thickness of storage materials or other filling mediums may be determined as needed. After filling the first gate conductor layer 21, the excess portion may be planarized by CMP (Chemical Mechanical Polishing).

In S514, the intra-group sacrificial layer 30 is etched through the hollowing-out hole 11 to obtain the body region 32.

FIG. 6E schematically shows a cross-sectional view of a structure of a body region during a manufacturing process of a NOR-type memory device according to an embodiment of the present disclosure.

For example, the silicon oxide in the hollowing-out hole 11 is etched by photolithography, and then the intra-group sacrificial layer 30 is laterally etched through the hollowing-out hole 11, as shown in FIG. 6E, so as to obtain the body region 32. An etching depth of the hollowing-out hole 11 should reach or exceed the source/drain region 31 of the lowest layer. The lateral etching method may be dry etching using sulfur fluoride, or wet etching using alternating cleaning with HF and hydrogen peroxide.

According to embodiments of the present disclosure, after obtaining the body region 32, the method of manufacturing a NOR-type memory device may, for example, further include:

In S515, a second filling layer 321 is grown in the body region 32 through the hollowing-out hole 11, and the second filling layer 321 is the first insulation layer or the stress layer.

FIG. 6F schematically shows a cross-sectional view of a structure of a body region during a manufacturing process of a NOR-type memory device according to another embodiment of the present disclosure. FIG. 6G schematically shows a cross-sectional view of a structure of a body region during a manufacturing process of a NOR-type memory device according to yet another embodiment of the present disclosure.

According to embodiments of the present disclosure, as shown in FIG. 6F, after obtaining the body region 32, the method of manufacturing a NOR-type memory device may, for example, further include the following steps S515′ and S516′.

In S515′, the third filling layer 323 is grown in the body region 32, as well as on the source/drain region 31 and the vertical channel 4 through the hollowing-out hole 11.

In S516′, the second gate conductor layer 322 is grown on the third filling layer 323 until the body region 32 is fully filled. At least one of the first filling layer 22 and the third filling layer 323 is a storage functional layer.

For example, the filling process of the third filling layer 323 and the second gate conductor layer 322 includes but is not limited to, for example, ALD (Atomic layer deposition), CVD (Chemical Vapor Deposition), and the like.

For example, as shown in FIG. 6G, from the view of the cross-section not passing through the hole and column, the second gate conductor layer 322 and the third filling layer 323 in the same layer of the device are communicated with each other. After completing the filling of the second gate conductor layer 322, the metal interconnection of each layer may be avoided through ALE to independently control each body region 32, or the back gates may be directly and uniformly connected to reduce the manufacturing process steps. Then, the excess gate conductor material is etched again to obtain the hollowing-out hole 11, and the hollowing-out hole 11 is filled with the same material as the third filling layer 323 or silicon oxide through ALD to obtain the filled hollowing-out column 10.

FIG. 6H schematically shows a cross-sectional view of a structure of a leading electrode during a manufacturing process of a NOR-type memory device according to an embodiment of the present disclosure.

According to embodiments of the present disclosure, as shown in FIG. 6H, the method of manufacturing a NOR-type memory device may, for example, further include the following steps S516 to S519.

In S516, a first leading electrode hole, which extends vertically relative to the substrate 1 to the source/drain region 31, is formed.

In S517, a second leading electrode hole, which extends vertically relative to the substrate 1 to the second gate conductor layer 322, is formed.

In S518, a third insulation layer is grown on the sidewalls of the first and second leading electrode holes.

In S519, a leading electrode is grown on the third insulation layer in the first leading electrode hole and the source/drain region 31 (i.e., the hole bottom of the first leading electrode hole) to obtain the first leading electrode 6. A leading electrode is grown on the third insulation layer in the second leading electrode hole and the second gate conductor layer 322 (i.e., the hole bottom of the second leading electrode hole) to obtain the second leading electrode 7.

For example, the leading electrode hole is etched by photolithography, and an insulating spacer is formed on the hole wall. Then the hole is filled with metal, and the excess metal is planarized by adopting CMP. Finally, a plurality of surface electrodes 8 are deposited on the hard mask and etched by photolithography, and the plurality of surface electrodes 8 are electrically connected to the first leading electrode 6 and the second leading electrode 7, respectively, to obtain a NOR-type memory device.

It may be understood that the leading electrode may be led out by punching as shown in FIG. 6H, or may be led out in a form of a step.

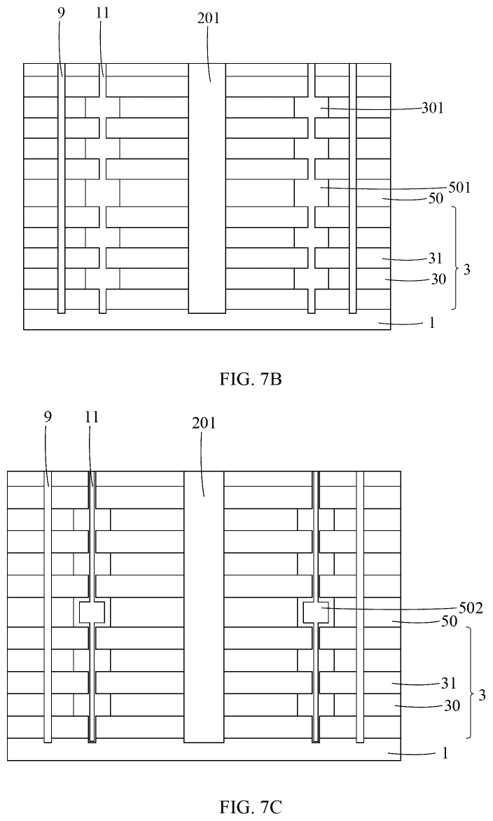

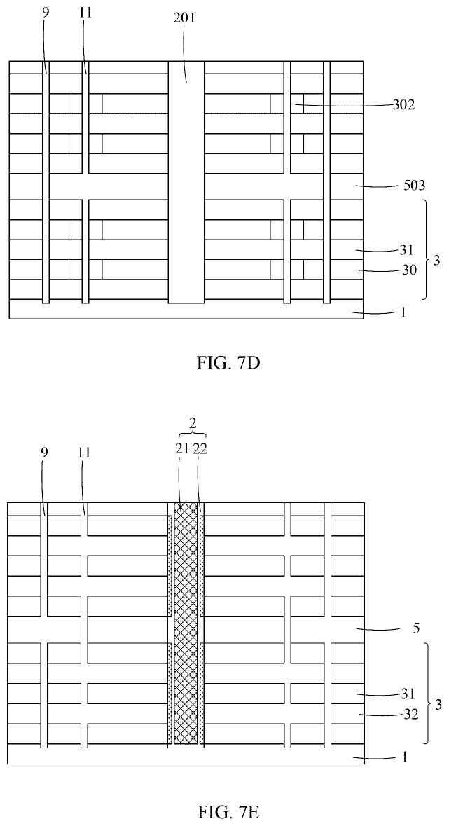

FIG. 7A schematically shows a cross-sectional view of a structure of a stack during a manufacturing process of a NOR-type memory device according to another embodiment of the present disclosure.

According to embodiments of the present disclosure, as shown in FIG. 7A, at least two device layers 3 are epitaxial on the substrate 1, where an inter-group sacrificial layer 50 is grown between respective device layers 3 of the at least two device layers 3, and a thickness of the inter-group sacrificial layer 50 is greater than a thickness of the intra-group sacrificial layer 30.

For example, the thickness of the inter-group sacrificial layer 50 may also be in a range of 5 nm to 500 nm, but the thickness of the inter-group sacrificial layer 50 needs to be greater than the thickness of the intra-group sacrificial layer 30. The material of the inter-group sacrificial layer 50 and the intra-group sacrificial layer 30 is, for example, silicon germanide.

FIG. 7B schematically shows a cross-sectional view of a structure of a trench obtained by etching a portion of a sacrificial layer during a manufacturing process of a NOR-type memory device according to an embodiment of the present disclosure. FIG. 7C schematically shows a cross-sectional view of a structure of a protection plug obtained by filling a trench with a medium during a manufacturing process of a NOR-type memory device according to an embodiment of the present disclosure. FIG. 7D schematically shows a cross-sectional view of a structure of an inter-group cavity obtained by etching a filling medium and an inter-group sacrificial layer during a manufacturing process of a NOR-type memory device according to an embodiment of the present disclosure.

As shown in FIG. 7B to FIG. 7D, after forming the support column 9, the hollowing-out hole 11, and the gate hole 20, the method of manufacturing a NOR-type memory device may, for example, further include the following steps S5111 to S5114.

In S5111, a portion of the intra-group sacrificial layer 30 and a portion of the inter-group sacrificial layer 50 are etched through the hollowing-out hole 11 to obtain an intra-group trench 301 and an inter-group trench 501.

For example, before the intra-group trench 301 and the inter-group trench 501 are obtained by etching through the hollowing-out hole 11, the gate hole 20 may be filled with a medium (such as silicon oxide) to obtain the gate column 201, so as to protect the hole structure of the gate hole 20.

In S5112, a filling medium is synchronously grown in the intra-group trench 301 and the inter-group trench 501 until the intra-group trench 301 is fully filled.

For example, when the intra-group trench 301 is fully filled, due to the thickness of the inter-group sacrificial layer 50 being greater than the thickness of the intra-group sacrificial layer 30, the inter-group sacrificial layer 50 is not fully filled with the medium, and there is a gap 502. The filling process includes but is not limited to, for example, ALD (Atomic Layer Deposition) and CVD (Chemical Vapor Deposition). The filling material includes but is not limited to stress materials such as silicon carbide, silicon germanide, and silicon nitride, common mediums such as silicon oxide, aluminum oxide, hafnium oxide, zirconia, and silicon oxynitride, and storage mediums such as aluminum oxide, hafnium oxide, zirconia, silicon oxide, silicon nitride, and silicon oxynitride.

In S5113, the filling medium in the inter-group trench 501 and the inter-group sacrificial layer 50 are selectively etched to obtain an inter-group cavity 503.

For example, the filling medium on the inner wall of the hollowing-out hole 11, the filling medium on the inner wall of the gap 502, and the inter-group sacrificial layer 50 are selectively etched to obtain a protection plug 302 for protecting each intra-group sacrificial layer 30. The process of etching the filling medium includes but is not limited to ALE (Atomic Layer Etching), RIE (Reactive Ion Etching), dry etching, HF wet etching, and other isotropic etching technologies. The process of etching the inter-group sacrificial layer 50 may be dry etching using sulfur fluoride, or high selective etching processes such as wet etching using alternating cleaning with HF and hydrogen peroxide.

In S5114, the inter-group cavity 503 is filled with an insulating medium to obtain a second insulation layer 5.

For example, the inter-group cavity 503 may be filled with silicon oxide, or air isolation may also be formed.

Then, the vertical channel 4 and the gate stack 2 may be prepared in the gate hole 20 using the same method as above, and will not be described in detail here.

FIG. 7E schematically shows a cross-sectional view of a structure of a body region during a manufacturing process of a NOR-type memory device according to another embodiment of the present disclosure.

According to embodiments of the present disclosure, as shown in FIG. 7E, etching the intra-group sacrificial layer through the hollowing-out hole to obtain the body region includes the following step S514′.

In S514′, the filling medium in the intra-group trench 301 and the intra-group sacrificial layer 30 are selectively etched through the hollowing-out hole 11 to obtain the body region 32.

For example, first, the silicon oxide in the hollowing-out hole 11 is etched by photolithography, and each protection plug 302 is removed by selective etching, and then each intra-group sacrificial layer 30 is etched to obtain the body region 32. Finally, a third filling layer 323 and a second gate conductor layer 322 are sequentially prepared in the body region 32, and the leading electrodes and the surface electrodes are prepared, so as to obtain a NOR-type memory device as shown in FIG. 2A. The method is the same as above and will not be described in detail here.

It should be noted that during the device manufacturing process, there will be a plurality of drilling processes. Each intra-group sacrificial layer 30 may be hollowed out through the initially etched hollowing-out hole 11, or each intra-group sacrificial layer 30 may be hollowed out through holes in other positions obtained through subsequent drilling steps.

A third aspect of the present disclosure provides an electronic device, including a NOR-type memory device according to any embodiment of the present disclosure. The electronic device includes, for example, a smart phone, a personal computer, a tablet computer, an artificial intelligence device, a wearable device, and a mobile power supply.

In summary, embodiments of the present disclosure propose a NOR-type memory device and a method of manufacturing the NOR-type memory device. By providing a vertical single crystal channel between the device layer and the gate stack, in combination with providing a side surface of the channel as a (100) crystal plane or a (110) crystal plane, the mobility of the channel is greatly improved, thereby improving the read and write performance of the NOR-type memory device. By providing an insulation layer or a stress layer in the body region, the device performance is further improved.

The details not covered in the method embodiment section are similar to those in the device embodiment section, please refer to the device embodiment section, and the details will not be repeated here.

It should be understood that the specific order or hierarchy of steps in the disclosed process are examples of exemplary methods. Based on design preferences, it should be understood that the specific order or hierarchy of steps in the process may be rearranged without departing from the scope of protection of the present disclosure. The accompanying method claims provide elements of various steps in an exemplary order, and are not intended to be limited to a specific order or hierarchy.

It should also be noted that directional terms mentioned in the embodiments, such as “up”, “down”, “front”, “back”, “left”, “right”, etc., are only the directions referring to the accompanying drawings and are not intended to limit the scope of protection of the present disclosure. Throughout the accompanying drawings, the same elements are represented by the same or similar reference signs. Conventional structures or constructions will be omitted when they may obscure the understanding of the present disclosure. In addition, shapes, sizes and positional relationships of the respective components in the figures do not reflect true sizes and proportions, and actual positional relationship.

In the detailed description described above, various features are combined together in a single embodiment to simplify the present disclosure. Such disclosure should not be interpreted as reflecting an intention that the embodiments of the claimed subject matter require more features than those clearly recited in each claim. Rather, as reflected in the appended claims, the present disclosure is in a state where there are fewer features than the disclosed individual embodiments. Therefore, the appended claims are hereby clearly incorporated into the detailed description, with each claim standing on its own as a separate preferred embodiment of the present disclosure.

In addition, terms “first” and “second” are only used for descriptive purposes and are not to be construed as indicating or implying relative importance or implicitly indicating the number of technical features indicated. Therefore, a feature defined with “first” or “second” may, explicitly or implicitly, include one or more of the feature. In the description of the present disclosure, unless otherwise specifically defined, “a plurality of” means at least two, such as two, three, etc. For a term “containing” used in the specification or the claims, such term is intended to be inclusive in a manner similar to the term “comprising”, just as “comprising” is interpreted when employed as a transitional word in the claims. Any one of term “or” used in the specification and the claims is intended to mean a “non-exclusive or”.

The specific embodiments described above further explain objectives, technical solutions and beneficial effects of the present disclosure in detail. It should be understood that the specific embodiments described above are only specific embodiments of the present disclosure, and should not be used to limit the present disclosure. Any modifications, equivalent substitutions, improvements and the like made within the spirit and principle of the present disclosure should be included in the protection scope of the present disclosure.

What is claimed is:

1. A NOR-type memory device, comprising:
a plurality of gate stacks extending vertically on a substrate, wherein the gate stack comprises a first gate conductor layer and a first filling layer;
at least one device layer surrounding a periphery of the gate stack and extending along a sidewall of the gate stack, wherein the device layer comprises at least two source/drain regions and at least one body region provided in a vertical direction, the source/drain regions and the body region are provided alternatively, and a memory cell is defined at an intersection of the gate stack and the body region; and
a vertical channel provided on a side of the device layer close to the gate stack, wherein the vertical channel is a single crystal channel and in contact with the first filling layer;
wherein at least one side surface of the gate stack in the vertical direction is a (100) crystal plane or a (110) crystal plane; and/or
wherein the body region adopts any one of following two structures:
the body region comprises a second filling layer, wherein the second filling layer is a first insulation layer or a stress layer and the stress layer is used to apply a stress to the vertical channel; or
the body region comprises a second gate conductor layer and a third filling layer, wherein the third filling layer is used to isolate the second gate conductor layer from the source/drain region and at least one of the first filling layer and the third filling layer is a storage functional layer.

2. The NOR-type memory device according to claim 1, wherein a material of the first insulation layer comprises silicon oxide, aluminum oxide, hafnium oxide, zirconia, and silicon oxynitride;
wherein a material of the stress layer comprises silicon carbide, silicon germanium, and silicon nitride.

3. The NOR-type memory device according to claim 1, wherein the storage functional layer comprises a tunneling layer, a charge capture layer, and a barrier layer stacked sequentially;
wherein the barrier layer is provided on a side close to the first gate conductor layer and/or the second gate conductor layer;
wherein a material of the barrier layer comprises at least one of aluminum oxide and silicon oxide, a material of the charge capture layer comprises hafnium oxide, zirconia, and silicon nitride, and a material of the tunneling layer comprises aluminum oxide, silicon oxide, and silicon oxynitride.

4. The NOR-type memory device according to claim 1, further comprising:
a first leading electrode and a second leading electrode;
wherein the first leading electrode is electrically connected to the source/drain region, and the second leading electrode is electrically connected to the second gate conductor layer.

5. The NOR-type memory device according to claim 4, further comprising:
a plurality of surface electrodes;
wherein the plurality of surface electrodes are electrically connected to the first leading electrode and the second leading electrode, respectively.

6. The NOR-type memory device according to claim 1, wherein a material of the vertical channel comprises monocrystalline silicon, silicon carbide, a III-V group compound, and graphene, and the material of the vertical channel is an in-situ doped material;
wherein when the vertical channel is a P-type metal oxide semiconductor, a doping element comprises sulfur and arsenic;
wherein when the vertical channel is an N-type metal oxide semiconductor, a doping element comprises boron.

7. The NOR-type memory device according to claim 1, wherein a thickness of the vertical channel is between 1 nm and 100 nm.

8. The NOR-type memory device according to claim 1, comprising at least two device layers;
wherein a second insulation layer is provided between respective device layers of the at least two device layers.

9. The NOR-type memory device according to claim 1, further comprising:
a plurality of support columns and a plurality of hollowing-out columns;
wherein the support column and the hollowing-out column penetrate through the device layer in the vertical direction, the support column is used to support the source/drain region, and the hollowing-out column is used to assist in hollowing out the body region.

10. The NOR-type memory device according to claim 9, wherein projections of the support columns, the hollowing-out columns, and the gate stacks on the substrate are arranged in a first direction;
wherein any one or more of the support columns, the hollowing-out columns, and the gate stacks have a plurality of rows of projections on the substrate, and each of the plurality of rows of projections is arranged in a cross manner or arranged in parallel in a second direction.

11. A method of manufacturing a NOR-type memory device, comprising:
epitaxially growing at least one device layer on a substrate, wherein the device layer comprises at least two source/drain regions and at least one intra-group sacrificial layer provided in a vertical direction, and the source/drain regions and the intra-group sacrificial layer are provided alternatively;
forming a plurality of support columns, a plurality of hollowing-out holes, and a plurality of gate holes, which extend vertically relative to the substrate to pass through the device layer;
epitaxially growing, through the gate hole, a vertical channel on a sidewall of the device layer;
forming a gate stack in the gate hole, wherein at least one side surface of the gate hole in the vertical direction is a (100) crystal plane or a (110) crystal plane, and the gate stack comprises a first gate conductor layer and a first filling layer provided between the first gate conductor layer and the vertical channel; and
etching the intra-group sacrificial layer through the hollowing-out hole, so as to obtain a body region;
wherein a memory cell is defined at an intersection of the gate stack and the body region.

12. The method according to claim 11, wherein after obtaining the body region, the method further comprises:
growing, through the hollowing-out hole, a second filling layer in the body region, wherein the second filling layer is a first insulation layer or a stress layer.

13. The method according to claim 11, wherein after obtaining the body region, the method further comprises:
growing, through the hollowing-out hole, a third filling layer in the body region and on the source/drain region and the vertical channel; and
growing a second gate conductor layer on the third filling layer until the body region is fully filled;
wherein at least one of the first filling layer and the third filling layer is a storage functional layer.

14. The method according to claim 13, further comprising:
forming a first leading electrode hole which extends vertically relative to the substrate to the source/drain region;
forming a second leading electrode hole which extends vertically relative to the substrate to the second gate conductor layer;
growing a third insulation layer on sidewalls of the first leading electrode hole and the second leading electrode hole;
growing a leading electrode on the third insulation layer in the first leading electrode hole and on the source/drain region, so as to obtain a first leading electrode; and
growing a leading electrode on the third insulation layer in the second leading electrode hole and on the second gate conductor layer, so as to obtain a second leading electrode.

15. The method according to claim 11, wherein at least two device layers are epitaxially grown on the substrate, wherein an inter-group sacrificial layer is grown between respective device layers of the at least two device layers, and a thickness of the inter-group sacrificial layer is greater than a thickness of the intra-group sacrificial layer;
wherein after forming the support column, the hollowing-out hole, and the gate hole, the method further comprises:
etching, through the hollowing-out hole, a portion of the intra-group sacrificial layer and a portion of the inter-group sacrificial layer, so as to obtain an intra-group trench and an inter-group trench;
synchronously growing a filling medium in the intra-group trench and the inter-group trench until the intra-group trench is fully filled;
selectively etching the filling medium in the inter-group trench and the inter-group sacrificial layer, so as to obtain an inter-group cavity; and
filling the inter-group cavity with an insulating medium to obtain a second insulation layer.

16. The method according to claim 15, wherein etching the intra-group sacrificial layer through the hollowing-out hole to obtain the body region comprises:
selectively etching, through the hollowing-out hole, the filling medium in the intra-group trench and the intra-group sacrificial layer, so as to obtain the body region.

17. The method according to claim 11, wherein epitaxially growing the vertical channel on the sidewall of the device layer through the gate hole comprises:
epitaxially growing the vertical channel on the sidewall of the device layer by using a reduced pressure chemical vapor deposition method.

18. The method according to claim 11, wherein forming the gate stack in the gate hole comprises:
growing the first filling layer on a side surface and a bottom surface of the gate hole; and
growing the first gate conductor layer on the first filling layer until the gate hole is fully filled, so as to obtain the gate stack.

19. An electronic device, comprising the NOR-type memory device according to claim 1.

20. The electronic device according to claim 19, wherein the electronic device comprises: a smart phone, a personal computer, a tablet computer, an artificial intelligence device, a wearable device, and a mobile power supply.
